(19) United States
(12) Patent Application Publication
(10) Pub. No.: US 2013/0133402 A1
(43) Pub. Date: May 30, 2013

(54) MULTI-LAYER CHIP FOR GAS CHROMATOGRAPHY AND FABRICATION METHOD THEREOF

(71) Applicant: Sanggoo KIM, Seoul (KR)

(72) Inventor: Sanggoo KIM, Seoul (KR)

(73) Assignee: KOREA BASIC SCIENCE INSTITUTE, Daejeon (KR)

(21) Appl. No.: 13/334,967

(22) Filed: Dec. 22, 2011

(30) Foreign Application Priority Data
Nov. 28, 2011 (KR) 10-2011-0125077

(51) Int. Cl. G01N 30/60; G03F 7/20

(52) U.S. Cl. 73/23.39; 430/320

(57) ABSTRACT

Disclosed herein are a multi-layer chip for gas chromatography and a method of fabricating the multi-layer chip. The multi-layer chip is fabricated by: forming fine channels at the same positions of a plurality of substrates using only a single photo mask and an alignment key; and stacking the substrates. That is, the multi-layer chip can be fabricated by a simple method, and the total length of the fine channels can be increase without a limit by stacking more substrates. In addition, layers of the substrates can be coated with different stationary phases, and a temperature control device can be attached to heat transfer contact portions of the multi-layer chip for controlling the temperature of the multi-layer chip rapidly and precisely. Therefore, the multi-layer chip may be useful for high-separability gas chromatography to separate and analyze an infinitesimal amount of a sample.

### CROSS-REFERENCES TO RELATED APPLICATION

This patent application claims the benefit of priority from Korean Patent Application No. 10-2011-0125077, filed on Nov. 28, 2011, the contents of which are incorporated herein by reference.

### BACKGROUND OF THE INVENTION

1. Field of the Invention The present disclosure relates to a multi-layer chip for gas chromatography and a method of fabricating the multi-layer chip.

2. Description of the Related Art

Generally, chromatography refers to an analysis method for separating ingredients of a sample by setting a solid or liquid as a stationary phase and a gas or liquid as a moving phase, injecting the sample to the moving phase while passing the moving phase through the stationary phase, and allowing the ingredients of the sample to be absorbed or distributed in the moving phase or the stationary phase at different rates.

Non-limiting examples that can be analyzed by chromatography include: (1) gases; (2) chemical substances; (3) biological substances such as DNAs, carbohydrates, lipids, peptides, proteins, and combinations thereof; (4) molecules; or (5) arbitrary combinations thereof. Substances separated by chromatography may be analyzed using various detecting units that can be attached to equipment. Currently, various chromatography methods and separation mechanisms are used, and much research is being conducted on chromatography.

Many chromatography methods have been developed for neural substance separation, medicine refinement, chemical substance refinement, etc.

According to the kinds of moving phases, chromatography can be classified into gas chromatography and liquid chromatography. In addition, according to a pressure applied to the moving phase, liquid chromatography can be classified into various types such as high pressure liquid chromatography (HPLC) which is also called ‘high performance liquid chromatography.’ These chromatography methods are now commercially available and used.

Thin layer chromatography using a glass or synthetic-resin substrate coated with silica gel is also widely used for simple analysis. In addition, ion exchange chromatography using ionic bonding for sample separation instead of using distribution coefficient difference has also been developed and currently used.

As described above, although various chromatography methods have been developed and commercially used, since such chromatography methods are basically based on physical properties of a sample such as distribution coefficient, molecular weight, and ionic characteristics, optimal separation and analysis conditions cannot be equally defined or determined for different samples. That is, optimal separation or analysis conditions are determined by interrelatedly selecting various items such as a stationary phase, a moving phase, a flowrate of the moving phase, a temperature of an oven in which distribution occurs, and a detector that detects a dissolved and separated sample according to the kind of a sample. Selection of analysis conditions of an analysis device largely affects results of chromatography analysis. That is, analysts have to select an optimal analyzing device and analysis conditions for each sample.

Particularly, gas chromatography devices have a simple structure mainly constituted by an injector, an analysis column, and a detector, but are highly precise, sensitive, and easily maintainable as compared with liquid chromatography devices such as HPLC devices. That is, gas chromatography devices are advantageous in simple, basic, and repetitive regular analyses and are widely used for those purposes.

When a mixture of various substances is analyzed by chromatography, separability is significantly affected by the length of a column and the variety of column polarities.

In photolithography, a pattern mask on which a desired pattern is drawn is placed over a wafer coated with photo resist, and light is emitted from a light source to the wafer through the pattern mask to form the desired pattern on the wafer. It may be said that the core technique of photolithography is use of light energy.

In detail, photo resist is uniformly applied to a semiconductor silicon substrate (wafer), and a mask (or reticle) on which a desired pattern is formed is placed over the wafer. At this time, for precise patterning, the mask is aligned with the wafer using marks formed on the mask and the wafer.

Next, light is emitted from a laser or mercury arc lamp to the wafer coated with the photoresist through the mask. Then, an image of the pattern is formed on the photoresist of the wafer.

Thereafter, the photoresist is exposed to a solution-based developer or etching plasma to selectively remove portions of the photoresist exposed to (or not exposed to) the light. In this way, the photoresist is patterned using the mask. The above-mentioned photolithography technique is called a photo process.

While the inventors studied methods of increasing the separability of gas chromatography chips by increasing column lengths and varying column polarities, the inventors found and invented a chip prepared by forming fine channels on wafers by photolithography, coating the wafers with various stationary phases, and stacking the wafers on one another. Thus, interconnected fine channels having different polarities could be formed on layers of the chip.

### SUMMARY OF THE INVENTION

One object of the present invention is to provide a multi-layer chip for gas chromatography.

Another object of the present invention is to provide a method of fabricating the multi-layer chip.

Still another object of the present invention is provide a method of analyzing a sample using the multi-layer chip.

In order to achieve the objects, the present invention provides a multi-layer chip for gas chromatography, the multi-layer chip including an upper substrate, an inner substrate, and a lower substrate,

wherein each of the upper and the lower substrate includes a fine gas passage on one or both sides thereof; the inner substrate includes fine gas passages on both sides thereof; and the substrates are placed on one another in a manner such that the fine gas passages are aligned to form fine channels,

wherein the upper substrate includes a hole as an inlet; the inner substrate includes a hole as a connection hole; and the lower substrate includes a hole as an outlet,

wherein the substrates include heat transfer contact portions at regions where the fine gas passages are not formed to control a temperature of the multi-layer chip.

The present invention also provides a method of fabricating a multi-layer chip for gas chromatography, the method including:

a first step of preparing a photo mask using a computer aided design (CAD) program so as to use the photo mask to form a fine channel pattern;

a second step of preparing a master by applying photo resist to a substrate fixed to an alignment key and forming a fine channel pattern on the substrate by a photolithography method using the photo mask prepared in the first step;

a third step of forming a fine channel in the substrate by etching the master preparing in the second step;

a fourth step of applying a stationary phase to the substrate in which the fine channel is formed in the third step; and

a fifth step of stacking substrates formed through the first to fourth steps in a manner such that fine channel patterns of the substrates face each other.

Furthermore, the present invention provides a method of analyzing a sample, the method including:

a first step of injecting a sample into an inlet of the multi-layer chip; and

a second step of analyzing the sample injected in the first step.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view illustrating an image of a fine channel pattern prepared using a computer aided design (CAD) program according to a first embodiment of the present invention;

FIG. 2 is a view illustrating a photograph of a glass wafer on which a fine channel is formed according to the first embodiment of the present invention;

FIG. 3 is an exploded view illustrating a stacking process of a chip according to the first embodiment of the present invention;

FIG. 4 is a view illustrating a large-scale photograph taken from a fine channel of the glass wafer formed according to the first embodiment of the present invention;

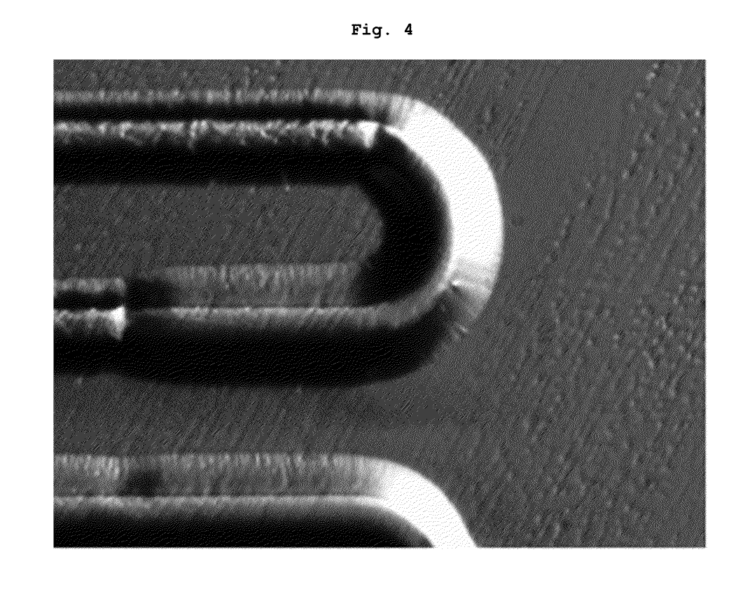

FIG. 5 is a view illustrating a large-scale photograph taken from a connection hole connecting fine channels of substrates stacked in a chip according to the first embodiment of the present invention;

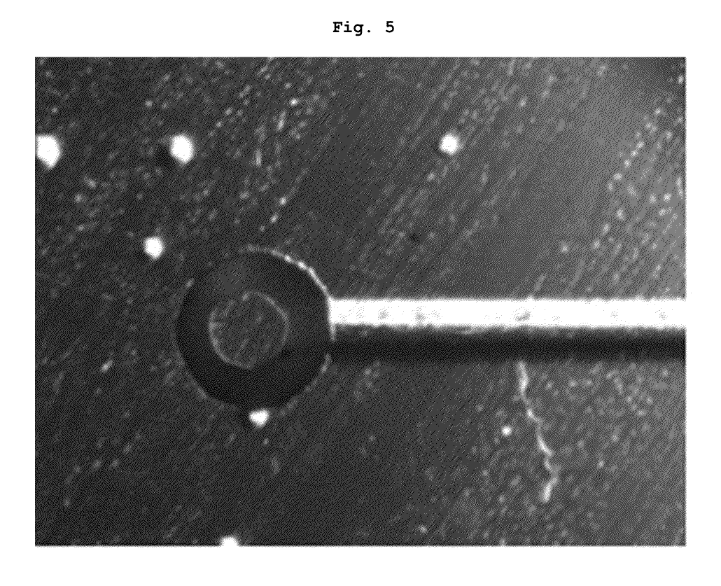

FIG. 6 is a view illustrating an image of a fine channel pattern prepared using a CAD program according to a second embodiment of the present invention;

FIG. 7 is a view illustrating a large-scale photograph taken from a fine channel of a glass wafer formed according to the second embodiment of the present invention;

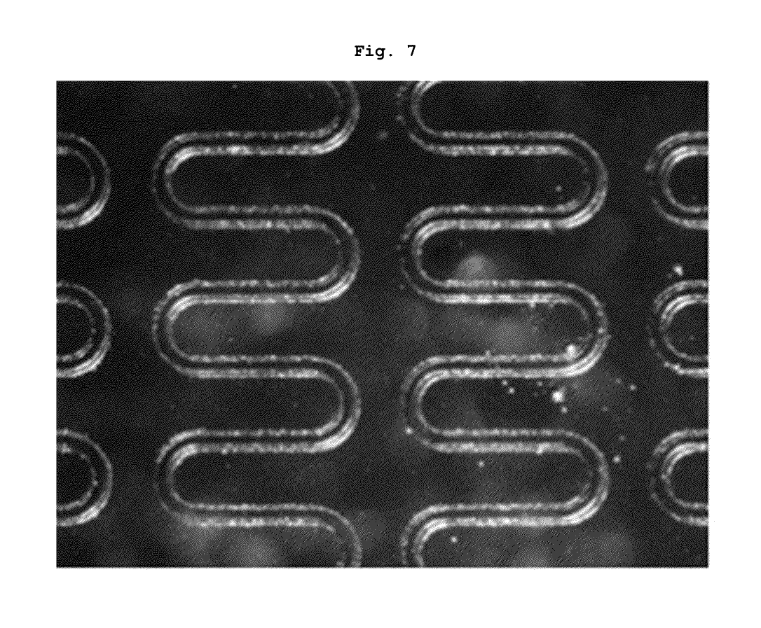

FIG. 8 is a view illustrating an image of a fine channel pattern prepared using a CAD program according to a third embodiment of the present invention;

FIG. 9 is a gas chromatography analysis graph obtained by analyzing a mixture using a chip according to an embodiment of the present invention; and

FIG. 10 is a view illustrating images taken using a surface analyzer from a fine gas passage of a substrate of an embodiment of the present invention.

### DESCRIPTION OF THE PREFERRED EMBODIMENTS

Features and advantages of the present invention will be more clearly understood by the following detailed description of the present preferred embodiments by reference to the accompanying drawings. It is first noted that terms or words used herein should be construed as meanings or concepts corresponding with the technical sprit of the present invention, based on the principle that the inventor can appropriately define the concepts of the terms to best describe his own invention. Also, it should be understood that detailed descriptions of well-known functions and structures related to the present invention will be omitted so as not to unnecessarily obscure the important point of the present invention.

Hereinafter, the present invention will be described in detail.

The present invention provides a multi-layer chip for gas chromatography, including an upper substrate, an inner substrate, and a lower substrate,

wherein each of the upper and the lower substrate includes a fine gas passage on one or both sides thereof; the inner substrate includes fine gas passages on both sides thereof; and the substrates are placed on one another in a manner such that the fine gas passages are aligned to form fine channels,

wherein the upper substrate includes a hole as an inlet; the inner substrate includes a hole as a connection hole; and the lower substrate includes a hole as an outlet,

wherein the substrates include heat transfer contact portions at regions where the fine gas passages are not formed to control a temperature of the multi-layer chip.

Preferably, the fine gas passages of the substrates are identical.

In addition, patterns of substrates facing each other and forming a layer may be identical, and patterns of layers may be different.

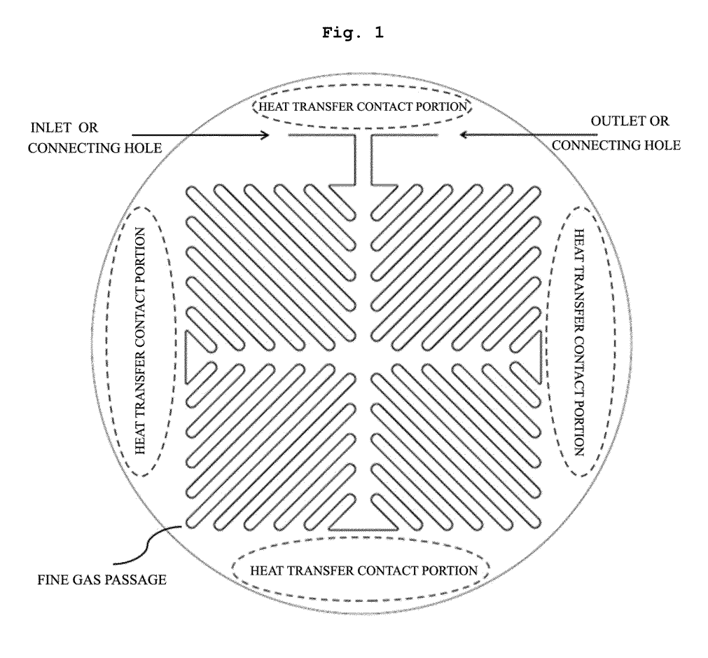

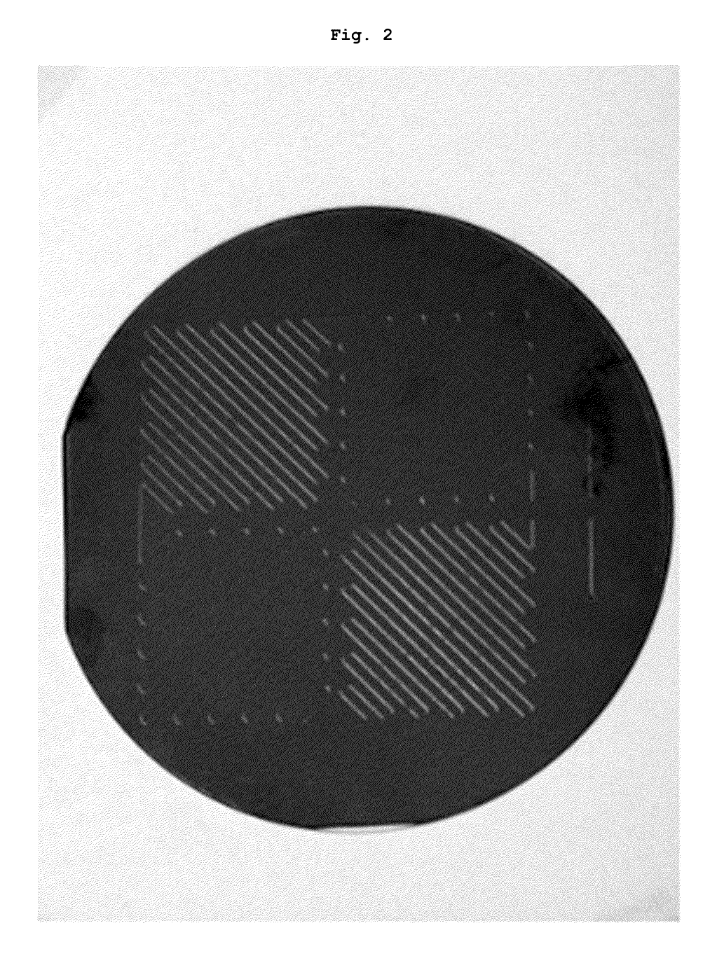

Hereinafter, the multi-layer chip for gas chromatography will be described in detail with reference to FIGS. 1 to 3.

In the multi-layer chip for gas chromatography of the present invention the substrates may be selected from glass wafers, quartz wafers, polydimethylsiloxane wafers, silicon wafers, silicate wafers, borosilicate wafers, and fused silica wafers.

In the multi-layer chip for gas chromatography of the present invention, the total length of the fine channels increases in proportion to the number of the substrates. That is, the total length of the fine channels may be increased without a limit for improving the separability of the multi-layer chip.

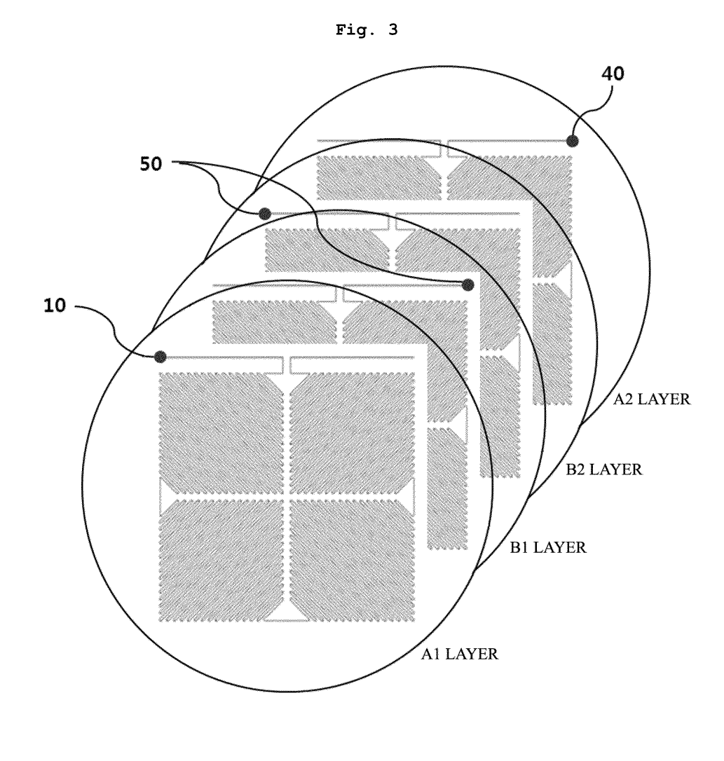

In the multi-layer chip for gas chromatography of the present invention, a hole may be formed at only one of both ends of a fine gas passage of a substrate (at a leading or trailing end, refer to FIG. 3) as an inlet, a connection hole, or an outlet.

In an embodiment, substrates may be placed in a manner such that a substrate in which a hole is formed at a leading end of a fine gas passage and a substrate in which a hole is formed at a trailing end of a fine gas passage are alternately placed on one another, so as to connect fine channels of layers of the substrates.

In the multi-layer chip for gas chromatography of the present invention, layers of the multi-layer chip may be coated with desired stationary phases so that the fine channels have desired polarities. In this case, substances included in a mixture sample may be simultaneously detected using the multi-layer chip. That is, the separability of the multi-layer chip may be improved.

The multi-layer chip for gas chromatography of the present invention may use stationary phases such as silica gels, alumina, molecular sieves, and porous polymers that are used as stationary phases for gas chromatography in the related art. In this way, the layers of the multi-layer chip of the present invention can have various polarities.

In the multi-layer chip for gas chromatography of the present invention, a temperature control device may be attached to the heat transfer contact portions to control the temperature of the multi-layer chip rapidly and precisely. Since temperature control is important in gas chromatography, the multi-layer chip of the present invention can provide improved effects because a temperature control device is attachable to the multi-layer chip.

The temperature control device may be a heating/cooling device having a rapid and precise temperature control function, such as a Peltier device.

In addition, the present invention provides a method for fabricating a multi-layer chip for gas chromatography, the method including:

a first step of preparing a photo mask using a computer aided design (CAD) program so as to use the photo mask to form a fine channel pattern;

a second step of preparing a master by applying photo resist to a substrate fixed to an alignment key and forming a fine channel pattern on the substrate by a photolithography method using the photo mask prepared in the first step;

a third step of forming fine channels in the substrate by etching the master preparing in the second step;

a fourth step of applying a stationary phase to the substrate in which the fine channel is formed in the third step; and

a fifth step of stacking substrates formed through the first to fourth steps in a manner such that fine channel patterns of the substrates face each other.

Hereinafter, the method of fabricating a multi-layer chip for gas chromatography will be described in detail with reference to FIGS. 1, 3, 6, and 8.

In the first step of the method of fabricating a multi-layer chip for gas chromatography according to the present invention, a photo mask is prepared using a CAD program so as to user the photo mask to form a fine channel pattern. In detail, a symmetric fine channel pattern such as those shown in FIGS. 1, 6, and 8 is designed using a CAD program, and the fine channel pattern is printed on a blank mask to form a photo mask that will be used to pattern a glass wafer.

At this time, it may be preferable to form a fine channel having a width of 10 μm to 100 μm.

In the second step of the method of fabricating a multi-layer chip for gas chromatography according to the present invention, photo resist is applied to a substrate fixed to an alignment key, and a master is prepared by forming a fine channel pattern on the substrate by a photolithography method using the photo mask prepared in the first step.

In detail, photo resist is applied to a glass wafer (substrate) by a method such as spin coating, and the photo resist is hardened by a photolithography method using the photo mask prepared in the second step. Then, portions of the photo resist that are not hardened are removed using a substance such as isopropanol. In this way, a master can be formed.

In the third step of the method of fabricating a multi-layer chip for gas chromatography according to the present invention, the master prepared in the second step is etched to prepare a substrate in which a fine channel is formed.

In detail, the master prepared in the second step is etched by an anisotropic wet etching method using an etchant such as a boric acid solution to remove portions of the glass wafer where the photoresist is not formed. In this way, a fine pattern can be formed.

In the fourth step of the method of fabricating a multi-layer chip for gas chromatography according to the present invention, the substrate in which the fine channel is formed in step 3 is coated with a stationary phase.

In detail, a method of coating a fine gas passage with a stationary phase may be varied depending on whether the method is performed before or after substrates (wafers) are bonded.

In the case where a chromatography chip is formed by bonding wafers by a low-temperature pressing method, fine gas passages may be coated with thin layers of stationary phases by using a spin coater before the wafers are bonded.

In the case where wafers are bonded in advance by a high-temperature method, fine gas passages may be coated with stationary phases by injecting the stationary phases into ends of the fine gas passages using a tube and a syringe and distributing the stationary phases in the form of films using compressed air.

The fifth step of the method of fabricating a multi-layer chip for gas chromatography according to the present invention, substrates prepared through the first to fifth steps are stacked on one another in a manner such that fine channel patterns of the substrates face each other.

In detail, as shown in FIG. 3, layers B1 and B2 each having fine channels on its both sides may be disposed between layers A1 and A2 each having a fine channel on its one side. In this way, a chip may be formed using layers A1, A2, B1, and B2 each formed in the third step.

At this time, as shown in FIG. 3, so as to connect an inlet 10 of the layer A1 to an outlet 40 of the layer A2 through each layer, connection holes 50 having an inner diameter of about 100 μm are formed through the layers B1 and B2 using a tool such as a sandblaster. Then, after a sodium silicate solution is applied to the layers A1, B1, B2, and A2 (glass wafers) using a spin coater, patterns of the layers A1, B1, B2, and A2 may be aligned using an alignment key, and the layers A1, B1, B2, and A2 may be bonded together by anodic bonding.

In a sandblasting method, a sucked abrasive is blasted to a target wafer together with air to machine the target wafer using kinetic energy of particles of the abrasive. That is, as the abrasive is sputtered onto the target wafer, effects similar to the effects of an etching process can be obtained.

In the above-described method, since gas passage patterns can be precisely aligned using an alignment key, dependency on skilled operators can be reduced. However, since only a portion of a wafer to which a sandblaster nozzle is pointed is etched unlike the case of plasma etching, the method may be effective when a wafer is etched in a direction perpendicular to the surface of the wafer.

Furthermore, the present invention provides a method of analyzing a sample, the method including:

a first step of injecting a sample into the inlet of the multi-layer chip for gas chromatography; and

a second step of analyzing the sample injected in the first step.

A temperature control device may be attached to the heat transfer contact portions of the multi-layer chip to control the temperature of the multi-layer chip rapidly and precisely.

The temperature control device may be a heating/cooling device having a rapid and precise temperature control function, such as a Peltier device.

As described above, the multi-layer chip of the present invention is fabricated by: forming fine channels at the same positions of a plurality of substrates using only a single photo mask and an alignment key; and stacking the substrates. That is, the multi-layer chip of the present invention can be fabricated by a simple method, and the total length of the fine channels can be increase without a limit by stacking more substrates. In addition, layers of the substrates can be coated with different stationary phases, and a temperature control device can be attached to heat transfer contact portions of the multi-layer chip for controlling the temperature of the multi-layer chip rapidly and precisely. Therefore, the multi-layer chip may be useful for high-separability gas chromatography to separate and analyze an infinitesimal amount of a sample.

Hereinafter, the present invention will be described in more detail with reference to the following examples. However, the present invention is not limited to the following examples.

### EXAMPLE 1

### Fabrication of Three-Layer Chip for Gas Chromatography

Step 1: Preparation of Photo Mask Using CAD Program

A symmetric fine channel pattern shown in FIG. 1 was drawn using a CAD program, and the fine channel pattern was printed on a blank mask (Photo Plotter Mask manufactured by Barco company) at a resolution of 40,000 dpi. In this way, a photo mask for patterning a glass wafer was fabricated.

The channel width of the fine channel pattern was set to about 50 μm.

Step 2: Preparation of Master Using Photolithography

Hexamethyldisilazane (HMDS) was applied to a glass wafer (4 inches) using a spin coater, and a photo resist (Model: SU-8, Manufacturer: Microchem) was applied to the glass wafer using the spin coater. The HMDS was used to enhance bonding between the glass wafer and the photo resist during an etching process.

Next, the photo mask prepared in Step 1 was disposed between the glass wafer and a glass plate (glass wafer/photo mask/glass plate), and ultraviolet (UV) rays were cast for 10 seconds to harden the photo resist.

Thereafter, portions of the photo resist exposed to UV rays were hardened using a developer solution (Model: SU-8 developer, Manufacturer: Microchem), and portions of the photo resist that were not hardened were removed using isopropanol. In this way, a master was prepared.

The same fine channel pattern was formed on the other side of the master through the same steps. The same fine channel pattern could be precisely formed on the other side of the master by using an alignment key.

In this way, a master having a fine channel pattern on one or both sides thereof could be prepared.

Step 3: Formation of Fine Channel

The master prepared in Step 2 was etched by a wet etching method using 49 volume % of boric acid solution so as to anisotropically remove portions of the glass wafer not covered with the photo resist. In this way, a fine channel was formed in the glass wafer of the master.

Specifically, the wet etching was performed at a rate of 10-15 μm/min for 5 minutes, and a fine channel having an average depth of about 50 μm was formed. Next, the photo resist remaining on the glass wafer was removed using a piranha buffer.

Step 4: Coating with Stationary Phase

Highly nonpolar polyethylene glycol (PEG) 350 was coated on fine gas passages as a stationary phase by two methods.

In the case where a chromatography chip was fabricated by bonding wafers by a low-temperature pressing method, the wafers were coated with thin layers of PEG 350 by using the spin coater (4,000 rpm, 60 seconds, 5 times), and then the wafers were bonded together.

In the case where wafers are bonded in advance by a high-temperature ..method, fine gas passages were coated with PEG 350 by injecting the PEG 350 into ends of the fine gas passages using a tube and a syringe and distributing the PEG 350 in the form of films using compressed air.

Step 5: Fabrication of Three-Layer Chip for Gas Chromatography

As shown in FIG. 3, layers B1 and B2 each having fine channels on its both sides were disposed between layers A1 and A2 each having fine channels on its one side. In this way, a chip was formed using the layers A1, A2, B2, and B3 that had been formed in Step 3.

In detail, as shown in FIG. 3, an inlet 10 of the layer A1 and an outlet 40 of the layer A2 were connected through each layer by forming connection holes 50 having an inner diameter of about 100 μm through the layers B1 and B2 as follows. After dry films (manufactured by TOK) were deposited on wafers having fine gas passage patterns, light was cast to the dry films deposited on the wafers through a pattern mask by using an mask aligner (model: EVG 6200, manufacturer: EVGroup), and the dry films were patterned by a developing process using sodium carbonate. Thereafter, the connection holes 50 were formed using a sandblaster (blasting pressure of about 0.5 MPa).

Next, a sodium silicate solution was applied to the layers (glass wafers) by using a spin coater, and after patterns of the layers were aligned, the layers were bonded together using an anodic bonding device (model: EVG 520HE Bonder, Manufacturer: EVGroup) under the conditions of 350° C. and 800-1,000 V.

In this way, a gas chromatography chip was fabricated, in which fine gas passages (having a length of about 2 m and an inner diameter of about 0.1 mm) were formed in 4-inch wafers.

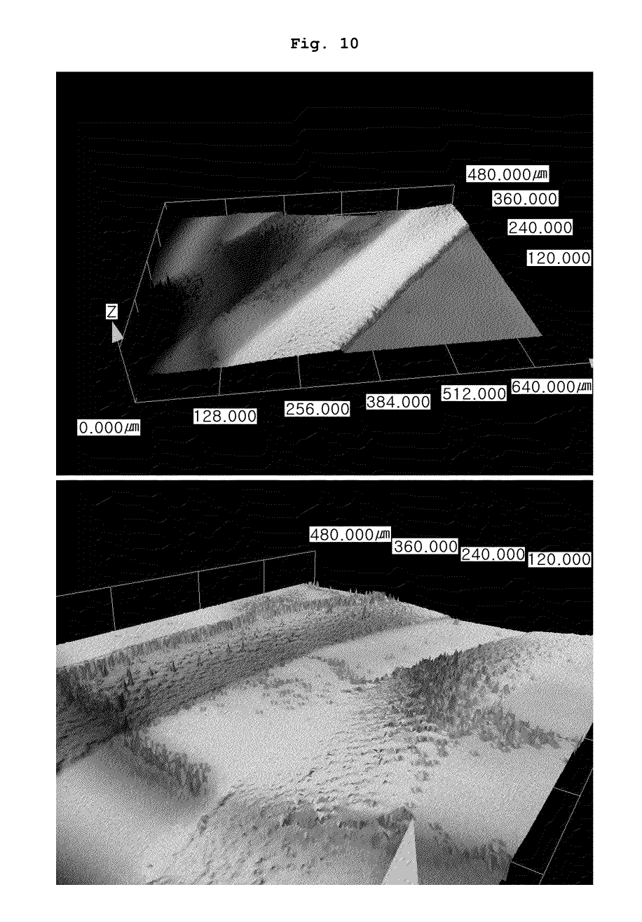

The fine gas passage of the substrate fabricated in Example 1 was observed using a surface analyzer (model: Dektak 150M, manufacturer: Veeco Instrument), and images of the fine gas passage are shown in FIG. 10.

### EXAMPLE 2

### Fabrication of Three-Layer Chip for Gas Chromatography

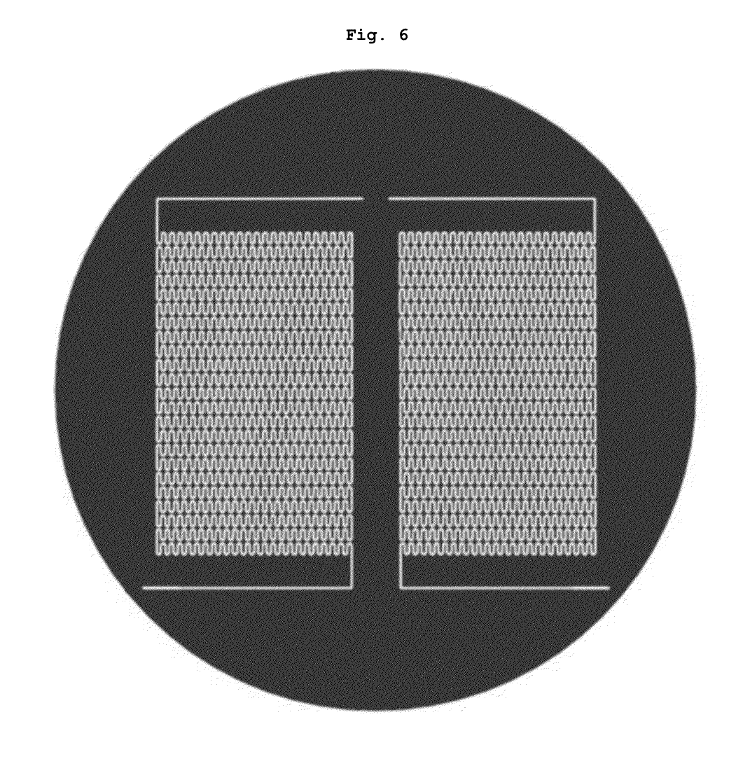

A three-layer chip for gas chromatography was manufactured in the same manner as Example 1 except that a symmetric fine channel pattern shown in FIG. 6 was drawn using a CAD program instead of drawing the symmetric fine channel pattern shown in FIG. 1.

### EXAMPLE 3

### Fabrication of Three-Layer Chip for Gas Chromatography

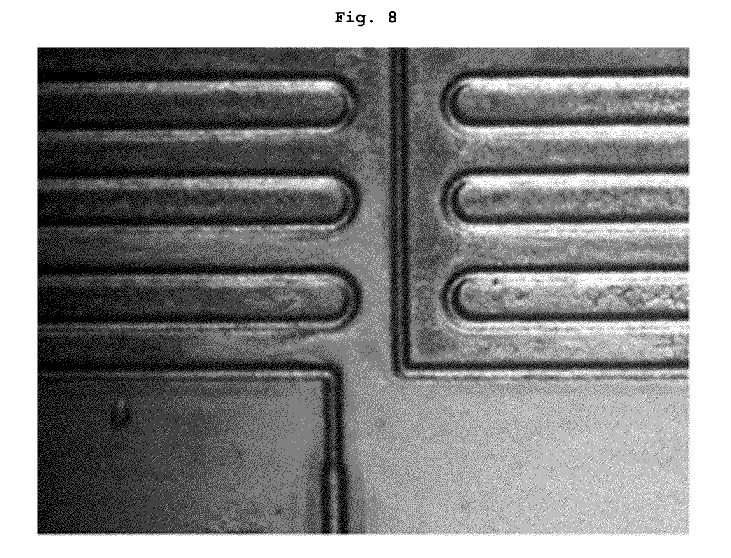

A three-layer chip for gas chromatography was manufactured in the same manner as Example 1 except that a symmetric fine channel pattern shown in FIG. 8 was drawn using a CAD program instead of drawing the symmetric fine channel pattern shown in FIG. 1.

### EXPERIMENTAL EXAMPLE 1

### Analysis Using Gas Chromatography Chip

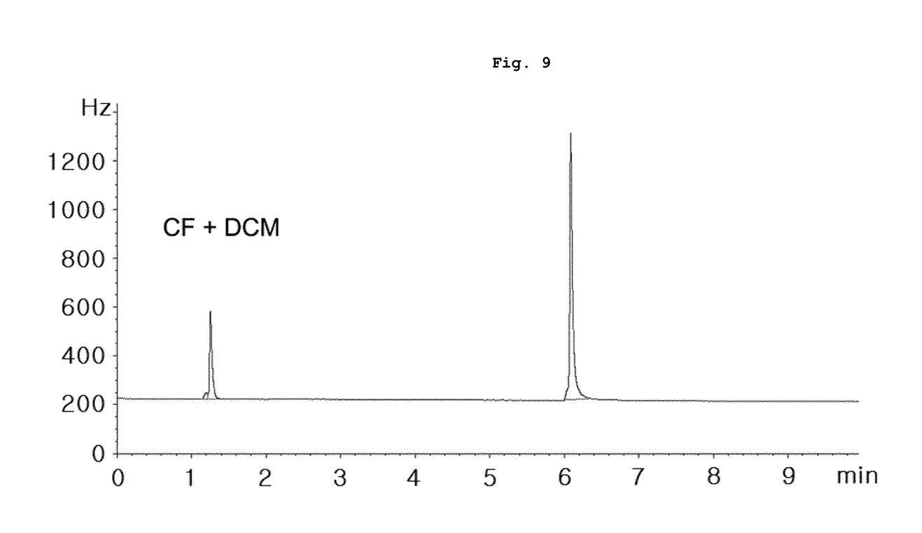

The three-layer chip for gas chromatography fabricated in Example 1 was connected to an electron capture detector (model: 6890 GC System, manufacturer: Hewlett Packard), and a 1/1000 diluted solution of chloroform and dichloromethane was analyzed. At that time, a split ratio was 1:20. Analysis results are shown in FIG. 9.

Referring to FIG. 9, peaks of chloroform and dichloromethane are clearly shown.

That is, even an infinitesimal amount of a sample can be analyzed at a sufficient separation resolution by using the chromatography chip of the present invention, and thus the chromatography chip of the present invention is useful for gas chromatography.

As described above, the multi-layer chip of the present invention is fabricated by: forming fine channels at the same positions of a plurality of substrates using only a single photo mask and an alignment key; and stacking the substrates. That is, the multi-layer chip of the present invention can be fabricated by a simple method, and the total length of the fine channels can be increase without a limit by stacking more substrates. In addition, layers of the substrates can be coated with different stationary phases, and a temperature control device can be attached to heat transfer contact portions of the multi-layer chip for controlling the temperature of the multi-layer chip rapidly and precisely. Therefore, the multi-layer chip may be useful for high-separability gas chromatography to separate and analyze an infinitesimal amount of a sample.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A multi-layer chip for gas chromatography, comprising an upper substrate, an inner substrate, and a lower substrate,
wherein each of the upper and the lower substrate comprises a fine gas passage on one or both sides thereof; the inner substrate comprises fine gas passages on both sides thereof; and the substrates are placed on one another in a manner such that the fine gas passages are aligned to form fine channels,
wherein the upper substrate comprises a hole as an inlet; the inner substrate comprises a hole as a connection hole; and the lower substrate comprises a hole as an outlet,
wherein the substrates comprise heat transfer contact portions at regions where the fine gas passages are not formed to control a temperature of the multi-layer chip.

2. The multi-layer chip as set forth in claim 1, wherein the substrates comprise at least one selected from the group consisting of a glass wafer, a quartz wafer, polydimethylsiloxane wafer, a silicon wafer, a silicate wafer, a borosilicate wafer, and a fused silica wafer.

3. The multi-layer chip as set forth in claim 1, wherein a total length of the fine channels increases in proportion to the number of the substrates.

4. The multi-layer chip as set forth in claim 1 is for gas-solid chromatography or gas-liquid chromatography.

5. The multi-layer chip as set forth in claim 1, wherein layers of the multi-layer chip are coated with desired stationary phases so that the fine channels have desired polarities.

6. The multi-layer chip as set forth in claim 1, wherein a temperature control device is attached to the heat transfer contact portions to control the temperature of the multi-layer chip rapidly and precisely.

7. The multi-layer chip as set forth in claim 6, wherein the temperature control device comprises a Peltier device.

8. A method for fabricating a multi-layer chip for gas chromatography, the method comprising:
a first step of preparing a photo mask using a CAD (computer aided design) program so as to use the photo mask to form a fine channel pattern;
a second step of preparing a master by applying photo resist to a substrate fixed to an alignment key and forming a fine channel pattern on the substrate by a photolithography method using the photo mask prepared in the first step;
a third step of forming a fine channel in the substrate by etching the master preparing in the second step;
a fourth step of applying a stationary phase to the substrate in which the fine channel is formed in the third step; and
a fifth step of stacking substrates formed through the first to fourth steps in a manner such that fine channel patterns of the substrates face each other.

9. The method as set forth in claim 8, wherein the first to third steps are performed to form the fine channel in one or both sides of the substrate.

10. The method as set forth in claim 8, wherein the alignment key is used to form fine channels at the same positions of a plurality of substrates.

11. The method as set forth in claim 8, wherein the fifth step is performed in a manner such that substrates coated with different stationary phases are stacked in layers.

12. The method as set forth in claim 8, wherein the substrates comprise at least one selected from the group consisting of a glass wafer, a quartz wafer, polydimethylsiloxane wafer, a silicon wafer, a silicate wafer, a borosilicate wafer, and a fused silica wafer.

13. The method set forth in claim 8 is for fabricating a multi-layer chip for gas-solid chromatography or gas-liquid chromatography.

14. A method of analyzing a sample, the method comprising:
a first step of injecting a sample into an inlet of a multi-layer chip fabricated by the method of claim 1; and
a second step of analyzing the sample injected in the first step.

15. The method as set forth in claim 14, wherein a temperature control device is attached to a heat transfer contact portion of the multi-layer chip to control a temperature of the multi-layer chip rapidly and precisely.
